(19) United States
(12) Patent Application Publication
(10) Pub. No.: US 2020/0030723 A1
(43) Pub. Date: Jan. 30, 2020

(54) CLEANING SOLUTION FILTER FOR LINEAR COATER, METHOD FOR FILTERING CLEANING SOLUTION AND LINEAR COATER

(71) Applicant: WUHAN CHINA STAR OPTOELECTRONICSTECHNOLOGY Co.,Ltd., Wuhan, Hubel (CN)

(72) Inventors: Wei LI, Wuhan, Hubei (CN); Tianhua YI, Wuhan, Hubei (CN)

(21) Appl. No.: 15/735,764

(22) PCT Filed: Nov. 7, 2017
(86) PCT No.: PCT/CN2017/109705

§ 371 Date: Dec. 12, 2017

(30) Foreign Application Priority Data
Oct. 27, 2017 (CN) 201711056351.4

(51) Int. Cl. B01D 29/03; B01D 61/00; B01D 3/14; B01D 5/00; B01D 36/00; G03F 7/16

(52) U.S. Cl. CPC B01D 29/03; B01D 61/00; B01D 3/145; B01D 5/006; B01D 2311/2669; B01D 36/003; G03F 7/16; B01D 2311/2649; B01D 5/0072

(57) ABSTRACT

A cleaning solution filter comprises a container body, at least one filter film and a delivering pipeline. One side of the container body is connected to a bottom of a cleaning tank for receiving a cleaning solution of the liner coater via a first pipeline. The at least one filter film is disposed in the container body, for filtering photoresists and photoresist additives in the cleaning solution. The delivering pipeline is for delivering the cleaning solution after filtering to the cleaning tank. The embodiments herein can filter the cleaning solution in the linear coater, extend the service life of the cleaning solution, and promote the coating effect.

### RELATED APPLICATIONS

The present application is a National Phase of International Application Number PCT/CN2017/109705, filed Nov. 7, 2017, and claims the priority of China Application No. 201711056351.4, filed Oct. 27, 2017.

### FIELD OF THE DISCLOSURE

The disclosure relates to a display technical field, and more particularly to a cleaning solution filter applied for a linear coater, a method for filtering cleaning solution and a linear coater.

### BACKGROUND

In the process of fabricating liquid crystal display panels, when the TFT array substrate is fabricated in the exposure stage, it is required to clean the glass substrate by a cleaner first before coating films thereon. Then, a dehydration baking procedure is performed. After cooling, the glass substrate is transmitted to a coating apparatus and coated with photoresists thereon. Next, a pre-baking procedure is performed again. The glass substrate is then transmitted to an exposure apparatus for defining patterns on the photoresists by using the photomasks disposed above the glass substrate. A development procedure is performed to illustrate the defined patterns.

A current linear coater is shown in FIG. 1, and the primary work process of the linear coater is depicted as follows.

A glass substrate 2′ is transmitted on a marble coating stage 11′ on a main frame 10′ of the linear coater.

An alignment device is applied to clamp the glass substrate 2′ and fix the offset thereof.

A vacuum adsorption is applied, by switching on a throttle 17′ to vacuum multiple channels 18′, for adsorbing the glass substrate 2′. After the glass substrate being fixed by vacuum adsorption, the alignment device would release the glass substrate.

A nozzle 13′ of a movable coating mechanism 12′ is moved to the top of a roller 14′ for performing a dummy coating, and then is moved by a motor to coat photoresists on the glass substrate 2′.

After coating, the vacuum adsorption is switched off, and thimbles in the channels 18′ top up the glass substrate 2′ Then, a robot arm is used to move the glass substrate 2′ to the next process stage.

In the process for fabricating the low temperature poly-silicon (LTPS) of the current technology, a planar layer is formed on a glass substrate by coating an organic photoresist thereon, and then the glass substrate is baked at a hot temperature about 220 degrees Celsius. The photoresists used for the planar layer are organic photoresists with strong adhesive, so it is necessary to perform the dummy coating frequently during the coating process. For example, in an actual operation, it is necessary to move the nozzle 13′ to the top of the roller 14′ for performing dummy coating every 40 minutes, to clean the nozzle 13′ for avoiding of being dogged. However, in the actual operation, some materials of the photoresists are insoluble in the cleaning solution. Even a lot of dummy coating procedures are done, the insoluble materials are still mixed within the cleaning solution and left in the cleaning tank 15′. These insoluble materials would form a layer of white mist remains on the roller 14′, and the roller scraper is unable to remove the white mist remains, thereby to make the defects, such as start mura, occurring on the glass substrate due to the remains during the photoresists coating. Because the planar layer cannot be reworked, the defects caused by the remains would result in the irreversible affect, even lead to product scrap.

### SUMMARY

For solving the above technical issues, the present invention provides a cleaning solution filter applied for a linear coater, a method for filtering cleaning solution and a linear coater, for filtering the cleaning solution in the linear coater, extending the service life of the cleaning solution, and promoting the coating effect.

For solving the above technical issues, the present invention provides a cleaning solution filter, applied for a linear coater. The cleaning solution filter comprises a container body, one side of the container body connecting to a bottom of a cleaning tank for receiving a cleaning solution of the liner coater via a first pipeline; at least one filter film, disposing in the container body, for filtering photoresists and photoresist additives in the cleaning solution; and a delivering pipeline, for delivering the cleaning solution after filtering to the cleaning tank.

In one embodiment, a distillation-condensation apparatus is disposed between the at least one filter film and the delivering pipeline, for performing a distillation-condensation process to the cleaning solution after filtering by the at least one filter film, to obtain a filter liquid after processing.

In one embodiment, the at least one filter film includes two filter films, one filter film is a photoresist filter film for filtering big molecules of the photoresists, the other filter film is an organic permeable membrane for filtering small molecules of the photoresist additives.

In one embodiment, the first pipeline includes a first switch disposed thereon; and the delivering pipeline includes a second switch and a pump disposed thereon.

Accordingly, in another respect, the present invention also provides a linear coater. The linear coater comprises a main frame, a coating stage disposed on the main frame for loading a glass substrate, a movable coating mechanism, a nozzle head, a roller, a cleaning tank for receiving a cleaning solution and a cleaning solution filter.

The cleaning solution filter further comprises a container body, one side of the container body connecting to a bottom of a cleaning tank for receiving a cleaning solution of the liner coater via a first pipeline; at least one filter film, disposing in the container body, for filtering photoresists and photoresist additives in the cleaning solution; and a delivering pipeline, for delivering the cleaning solution after filtering to the cleaning tank.

In one embodiment, a distillation-condensation apparatus is disposed between the at least one filter film and the delivering pipeline, for performing a distillation-condensation process to the cleaning solution after filtering by the at least one filter film, to obtain a filter liquid after processing.

In one embodiment, the at least one filter film includes two filter films, one filter film is a photoresist filter film for filtering big molecules of the photoresists, the other filter film is an organic permeable membrane for filtering small molecules of the photoresist additives.

In one embodiment, the first pipeline includes a first switch disposed thereon; and the delivering pipeline includes a second switch and a pump disposed thereon.

Accordingly, in one further respect, the present invention also provides a method for filtering cleaning solution, applied to the linear coater depicted above. The method for filtering cleaning solution comprises the following steps.

Step S10 is delivering the cleaning solution in the cleaning tank to the cleaning solution filter, after the nozzle head performing a dummy coating procedure on the roller;

Step S11 is filtering the cleaning solution by the at least one filter film;

Step S13 is delivering back the cleaning solution after filtering to the cleaning tank.

In specific, the step S11 is filtering big molecules of the photoresists by a photoresist filter film; and filtering small molecules of the photoresist additives by an organic permeable membrane.

In one embodiment, between the step S11 and the step S13, the method for filtering cleaning solution further comprises a step S12 of performing a distillation-condensation process by using the distillation-condensation apparatus to the cleaning solution, after filtering by the at least one filter film, to obtain a filter liquid after processing.

The embodiments of the present invention have following advantages:

In the embodiments of the present invention, a cleaning solution filter, disposed on a linear coater to connect with a cleaning tank of the linear coater, can filter the residual photoresists and photoresist additives in the cleaning solution, thereby to ensure the purity of the cleaning solution and maintain the surface of the roller bright and clean, and promote the coating effect of glass substrates. While the product yield is improved, the replacement period of the cleaning solution is extended greatly, for example, from two days to two months, thereby to decrease the usage of the cleaning solution and reduce costs.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a structural view of a current linear coater;

FIG. 2 is a structural view of a linear coater in one embodiment provided by the present invention; and

FIG. 3 is a schematic view illustrating the connection between the cleaning solution filter and the cleaning tank.

### DETAILED DESCRIPTION OF PREFERRED EMBODIMENTS

In order to make the purpose, technical scheme and advantages of the present invention more clear and obvious, the present invention will be further illustrated in detail in combination with accompanying drawings and embodiments hereinafter. The specific structural and functional details disclosed herein are only representative and are intended for describing exemplary embodiments of the disclosure. However, the disclosure can be embodied in many forms of substitution, and should not be interpreted as merely limited to the embodiments described herein.

It should be noted, for avoiding unnecessary details obscuring the present invention, in the drawings and description only the structures and/or processing steps closely related to the scheme of the present invention are illustrated, and other details not directly related to the present invention are omitted.

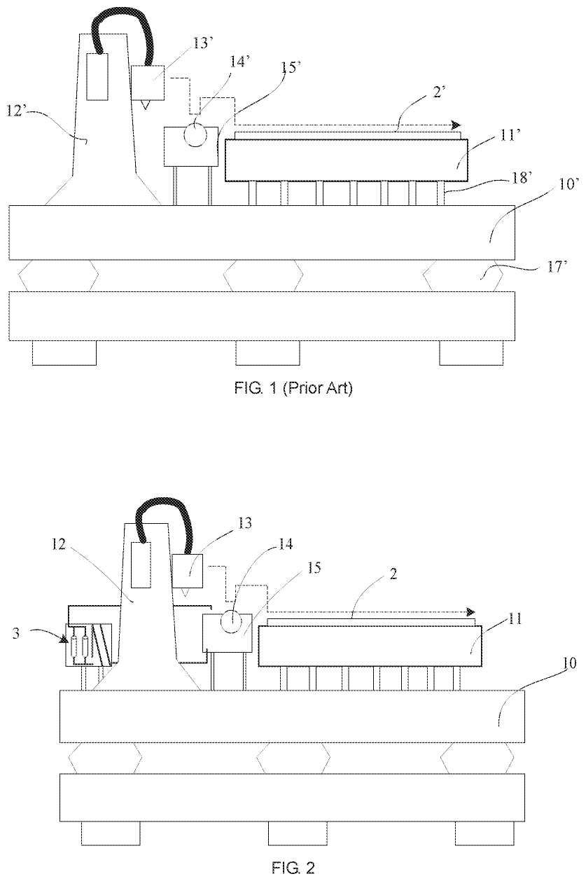

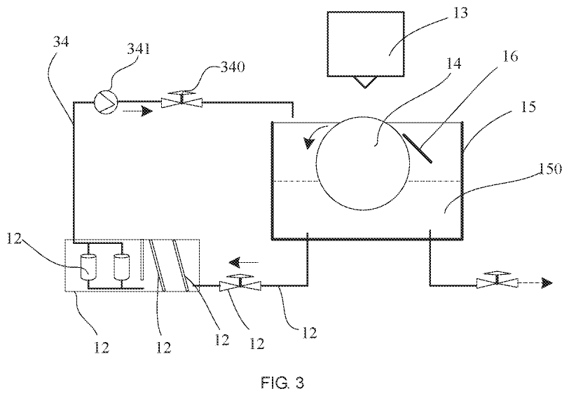

As shown in FIG. 2, a structural view of a linear coater in one embodiment provided by the present invention is illustrated. Also referring to FIG. 3, the linear coater comprises a main frame 1, a coating stage 11 disposed on the main frame 1 for loading a glass substrate 2, a movable coating mechanism 12, a nozzle head 13 connected to the movable coating mechanism 12, a roller 14, a cleaning tank 15 for receiving a cleaning solution 150, a scraper 16 disposed next to the roller 14 and a cleaning solution filter 3.

The cleaning solution filter 3 comprises a container body 30, at least one filter film and a delivering pipeline 34. One side of the container body 30 is connected to a bottom of the cleaning tank 15 for receiving the cleaning solution 150 of the liner coater via a first pipeline 31.

The at least one filter film is disposed in the container body 30 for filtering photoresists and photoresist additives in the cleaning solution. In an embodiment, the at least one filter film includes two filter films, one filter film is a photoresist filter film 32 for filtering big molecules of the photoresists, the other filter film is an organic permeable membrane 33 for filtering small molecules of the photoresist additives. One arrangement of two filter films, arranged side by side, is shown in FIGS. It is understandable, other arrangement, such as arranged up and down, is also fine.

The delivering pipeline 34 is applied for delivering the cleaning solution after filtering to the cleaning tank.

In an embodiment, a distillation-condensation apparatus 35 is disposed between the at least one filter film and the delivering pipeline 34, for performing a distillation-condensation process to the cleaning solution after filtering by the at least one filter film, to obtain a filter liquid after processing.

In one embodiment, the first pipeline 31 includes a first switch 310 disposed thereon, and the delivering pipeline 34 includes a second switch 340 and a pump 341 disposed thereon.

Accordingly, in one further respect, the present invention also provides a method for filtering cleaning solution, applied to the linear coater shown in FIG. 2 and FIG. 3. The method for filtering cleaning solution comprises the following steps.

Step S10 is delivering the cleaning solution in the cleaning tank to the cleaning solution filter, after the nozzle head 13 performing a dummy coating procedure on the roller 14. In specific, the step S10 could be done by switching on the first switch 310 on the first pipeline 31.

Step S11 is filtering the cleaning solution by the at least one filter film. In specific, the step S11 is filtering big molecules of the photoresists by a photoresist filter film 32, and filtering small molecules of the photoresist additives by an organic permeable membrane 33.

Step S12 is performing a distillation-condensation process by using the distillation-condensation apparatus 35 to the cleaning solution after filtering by the at least one filter film, to obtain a filter liquid after processing.

Step S13 is delivering back the cleaning solution after filtering to the cleaning tank 15. In specific, Step S13 can be done by the cooperation of the second switch 340 and the pump 341 of the delivering pipeline 34. It is understandable, in some embodiments, the delivery of the cleaning solution can also be achieved without the pump.

The embodiments of the present invention have following advantages:

In the embodiments of the present invention, a cleaning solution filter, disposed on a linear coater to connect with a cleaning tank of the linear coater, can filter the residual photoresists and photoresist additives in the cleaning solution, thereby to ensure the purity of the cleaning solution, maintain the surface of roller bright and clean, and promote the coating effect of glass substrates. While the product yield is improved, the replacement period of the cleaning solution is extended greatly, for example, from two days to two months, thereby to decrease the usage of the cleaning solution and reduce costs.

It should be noted that, in this disclosure, relational terms, such as first and second, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises . . . a” does not, without more constraints, preclude the existence of additional identical elements in the process, method, article, or apparatus that comprises the element.

The foregoing contents are detailed description of the disclosure in conjunction with specific preferred embodiments and concrete embodiments of the disclosure are not limited to these descriptions. For the person skilled in the art of the disclosure, without departing from the concept of the disclosure, simple deductions or substitutions can be made and should be included in the protection scope of the application.

What is claimed is:

1. A cleaning solution filter, applied for a linear coater, comprising:
a container body, one side of the container body connecting to a bottom of a cleaning tank for receiving a cleaning solution of the liner coater via a first pipeline;
at least one filter film, disposing in the container body, for filtering photoresists and photoresist additives in the cleaning solution; and
a delivering pipeline, for delivering the cleaning solution after filtering to the cleaning tank.

2. The cleaning solution filter according to claim 1, wherein a distillation-condensation apparatus is disposed between the at least one filter film and the delivering pipeline, for performing a distillation-condensation process to the cleaning solution after filtering by the at least one filter film, to obtain a filter liquid after processing.

3. The cleaning solution filter according to claim 2, wherein the at least one filter film includes two filter films, one filter film is a photoresist filter film for filtering big molecules of the photoresists, the other filter film is an organic permeable membrane for filtering small molecules of the photoresist additives.

4. The cleaning solution filter according to claim 2, wherein the first pipeline includes a first switch disposed thereon; and the delivering pipeline includes a second switch and a pump disposed thereon.

5. A linear coater, comprising a main frame, a coating stage disposed on the main frame for loading a glass substrate, a movable coating mechanism, a nozzle head, a roller, a cleaning tank for receiving a cleaning solution and a cleaning solution filter, wherein the cleaning solution filter comprises:
a container body, one side of the container body connecting to a bottom of the cleaning tank for receiving the cleaning solution of the liner coater via a first pipeline;
at least one filter film, disposing in the container body, for filtering photoresists and photoresist additives in the cleaning solution; and
a delivering pipeline, for delivering the cleaning solution after filtering to the cleaning tank.

6. The linear coater according to claim 5, wherein a distillation-condensation apparatus is disposed between the at least one filter film and the delivering pipeline, for performing a distillation-condensation process to the cleaning solution after filtering by the at least one filter film, to obtain a filter liquid after processing.

7. The linear coater according to claim 6, wherein the at least one filter film includes two filter films, one filter film is a photoresist filter film for filtering big molecules of the photoresists, the other filter film is an organic permeable membrane for filtering small molecules of the photoresist additives.

8. The linear coater according to claim 7, wherein the first pipeline includes a first switch disposed thereon; and the delivering pipeline includes a second switch and a pump disposed thereon.

9. A method for filtering cleaning solution, applied to a linear coater, wherein the linear coater comprises a main frame, a coating stage disposed on the main frame for loading a glass substrate, a movable coating mechanism, a nozzle head, a roller, a cleaning tank for receiving a cleaning solution and a cleaning solution filter, wherein the cleaning solution filter further comprises a container body, one side of the container body connecting to a bottom of the cleaning tank for receiving the cleaning solution of the liner coater via a first pipeline, at least one filter film, disposing in the container body, for filtering photoresists and photoresist additives in the cleaning solution, and a delivering pipeline, for delivering the cleaning solution after filtering to the cleaning tank, wherein the method for filtering cleaning solution comprises:
a step S10 of delivering the cleaning solution in the cleaning tank to the cleaning solution filter, after the nozzle head performing a dummy coating procedure on the roller;
a step S11 of filtering the cleaning solution by the at least one filter film; and
a step S13 of delivering back the cleaning solution after filtering to the cleaning tank.

10. The method for filtering cleaning solution according to claim 9, wherein the step S11 further comprises: filtering big molecules of the photoresists by a photoresist filter film; and filtering small molecules of the photoresist additives by an organic permeable membrane.

11. The method for filtering cleaning solution according to claim 10, wherein, between the step S11 and the step S13, further comprises: a step S12 of performing a distillation-condensation process by using the distillation-condensation apparatus to the cleaning solution, after filtering by the at least one filter film, to obtain a filter liquid after processing.
